(19) United States
(12) Patent Application Publication
(10) Pub. No.: US 2026/0128063 A1
(43) Pub. Date: May 7, 2026

(54) SEMICONDUCTOR DEVICE AND METHOD OF MANUFACTURING A SEMICONDUCTOR DEVICE

(71) Applicant: SK hynix Inc., Icheon-si Gyeonggi-do (KR)

(72) Inventor: Jong Hoon KIM, Icheon-si Gyeonggi-do (KR)

(73) Assignee: SK hynix Inc., Icheon-si Gyeonggi-do (KR)

(21) Appl. No.: 19/075,136

(22) Filed: Mar. 10, 2025

(30) Foreign Application Priority Data
Nov. 5, 2024 (KR) 10-2024-0155194

(51) Int. Cl. G11C 5/06; H01L 23/00; H10B 41/40; H10B 43/40; H10D 64/66

(52) U.S. Cl. CPC G11C 5/06; H10B 41/40; H10B 43/40; H10D 64/661; H10W 90/791

(57) ABSTRACT

A semiconductor device includes: a first stack including first material layers and second material layers that are alternately stacked; a penetration structure extending through the first stack and including an air gap; and a second stack located under the first stack and Including a key pattern located to correspond to the air gap.

### CROSS-REFERENCE TO RELATED APPLICATION

The present application claims priority under 35 U.S.C. § 119 (a) to Korean Patent Application No. 10-2024-0155194 filed on Nov. 5, 2024, in the Korean Intellectual Property Office, which application is incorporated herein by reference.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first stack including first material layers and second material layers, the first insulating layers are alternately stacked with the second insulating layers in a vertical direction; a penetration structure extending in the vertical direction through the first stack and including an air gap; and a second stack located under the first stack and including a key pattern located to overlap with the air gap in the vertical direction.

In an embodiment, a semiconductor device may include: a stack located in a scribe lane region and including first material layers and second material layers, the first material layers are alternately stacked with the second material layers in a vertical direction; a metal liner extending in the vertical direction through the stack; an insulating liner surrounding the metal liner; an air gap located inside the metal liner; and an interlayer insulating layer overlapping the stack in the vertical direction.

In an embodiment, a method of manufacturing a semiconductor device may include: forming a first stack on a substrate; forming a first opening extending into the substrate through the first stack; forming a sacrificial layer in the first opening; forming a second stack on the first stack; etching the substrate so that the sacrificial layer is exposed; forming a second opening by removing the sacrificial layer; and forming an air gap in the second opening.

In an embodiment, a method of manufacturing a semiconductor device may include: forming a stack; forming a contact plug penetrating through the stack; forming an opening extending through the stack; forming an insulating layer inside the opening and above the stack; forming a hard mask layer on the insulating layer to include an overhang structure in the opening; forming a mask pattern on the hard mask layer; forming a contact hole by etching the insulating layer using the mask pattern as an etching barrier, the contact hole exposing the contact plug; forming a via in the contact hole; and forming a metal liner in the opening, the metal liner including an air gap.

### BRIEF DESCRIPTION OF THE DRAWINGS

FIGS. 1A, 1B, 1C, 1D, and 1E are diagrams illustrating the structure of a semiconductor device in accordance with an embodiment.

FIGS. 2A and 2B are diagrams illustrating the structure of a semiconductor device in accordance with an embodiment.

FIGS. 3A and 3B are diagrams illustrating the structure of a semiconductor device in accordance with an embodiment.

FIGS. 4A, 4B, 4C, 4D, and 4E are diagrams for describing a manufacturing method of a semiconductor device in accordance with an embodiment.

FIGS. 5A, 5B, and 5C are diagrams for describing a manufacturing method of a semiconductor device in accordance with an embodiment.

FIGS. 6A, 7A, 8A, 9A, 10A, 11A, 12A, 13A, 14A, 15A, 16A, and 17A and FIGS. 6B, 7B, 8B, 9B, 10B, 11B, 12B, 13B, 14B, 15B, 16B, and 17B are diagrams for describing a manufacturing method of a semiconductor device in accordance with an embodiment.

FIG. 18 is a configuration diagram of a semiconductor device according to an embodiment of the present disclosure.

FIG. 19 is a configuration diagram of a semiconductor device according to an embodiment of the present disclosure.

### DETAILED DESCRIPTION

Various embodiments are directed to a semiconductor device having a stable structure and improved characteristics and a manufacturing method of the semiconductor device.

In an embodiment, by stacking memory cells in three dimensions, it is possible to improve the degree of integration of a semiconductor device. It is also possible, in an embodiment, to provide a semiconductor device having a stable structure and improved reliability.

Hereafter, embodiments in accordance with the technical concept of the present disclosure will be described with reference to the accompanying drawings. Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

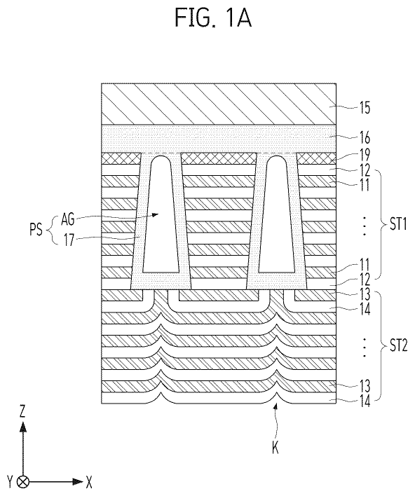

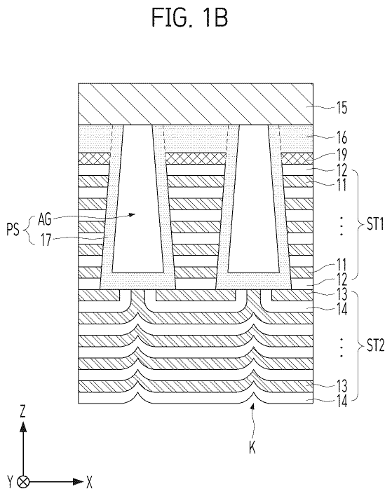

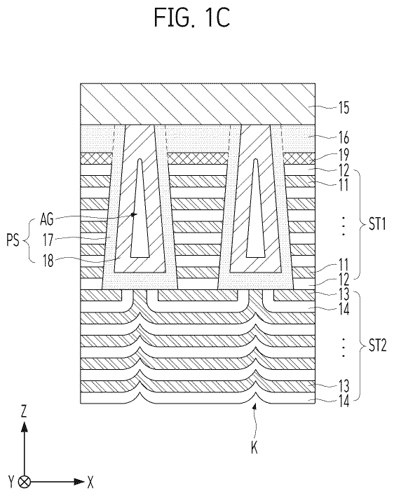

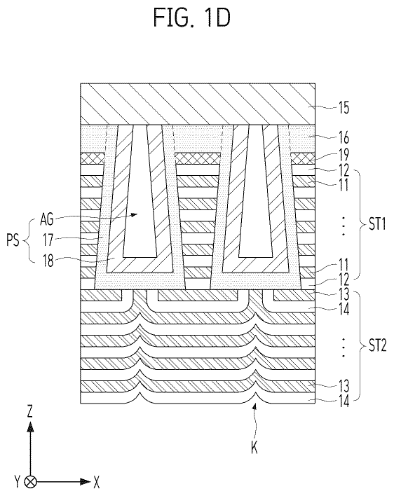

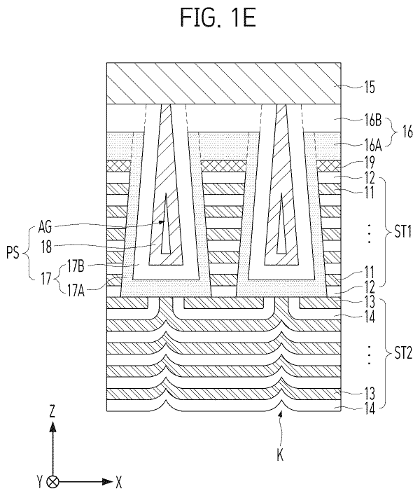

FIGS. 1A to 1E are diagrams illustrating the structure of a semiconductor device in accordance with an embodiment.

Referring to FIGS. 1A to 1E, the semiconductor device may include a first stack ST1, a second stack ST2, a penetration structure PS, and a metal pattern 15. The semiconductor device may further include a conductive pattern 19 and an interlayer insulating layer 16. For reference, the number of stacks included in the semiconductor device may be changed. The semiconductor device might not include the second stack ST2 or may further include a third stack ST3.

The first stack ST1 may include first material layers 11 and second material layers 12 that are alternately stacked. In an embodiment, the first material layers 11 and second material layers 12 may be alternately stacked in a stacking direction as shown in FIG. 1A. In an embodiment, the stacking direction may be a vertical direction (i.e., Z direction). In an embodiment, the surface of a first material layer 11 may form a plane by extending in horizontal directions (i.e., X and Y directions). The first material layers 11 may each include a material having a high etching selectivity with respect to the second material layers 12. As an example, the first material layers 11 may each include nitride, and the second material layers 12 may each include oxide. The first material layers 11 may each include a conductive material, and the second material layers 12 may each include an insulating material.

The penetration structure PS may be located in the first stack ST1. The penetration structure PS may extend through the first stack ST1, and may extend in the vertical direction. The penetration structure PS may have a cross section with a tapered shape, and may have a smaller width at an upper portion thereof than at a lower portion thereof. The penetration structure PS may include an air gap AG. The air gap AG may be an empty space that is not filled with a material layer. In an embodiment, the air gap AG may be an empty space including a gas. In an embodiment, the air gap AG may be an empty space including a gas that is not limited to air. In an embodiment, the air gap AG may be an empty space that is not filled with a material layer and does not include air. In an embodiment, the air gap AG may be an empty space that is not filled with a material layer and includes a gas that might or might not include air.

The second stack ST2 may be located under the first stack ST1. The second stack ST2 may include third material layers 13 and fourth material layers 14 that are alternately stacked. As an example, the third material layers 13 may each include nitride, and the fourth material layers 14 may each include oxide. The third material layers 13 may each include a conductive material, and the fourth material layers 14 may each include an insulating material. The third material layers 13 may include the same material as the first material layers 11, and the fourth material layers 14 may include the same material as the second material layers 12.

The penetration structure PS may be located over the second stack ST2, and the second stack ST2 may include a key pattern K located to correspond to the penetration structure PS. The key pattern K may be located on a surface of the second stack ST2, and may be a pattern formed by a stacked shape of the third and fourth material layers 13 and 14. The third and fourth material layers 13 and 14 may be stacked in a shape in which they are recessed toward the penetration structure PS, and a groove of a recessed region may be the key pattern K.

In an embodiment, the concave portions of the third and fourth material layers 13 and 14 forming a key pattern K may face away from the penetration structure PS while the convex portions of the third and fourth material layers 13 and 14 forming the key pattern may face towards the penetration structure PS. In an embodiment, a key pattern K may be located to correspond to an air gap AG by vertically overlapping with a penetration structure PS including the air gap AG. For example, the key pattern K, is located on the upper surface of the fourth material layer 14 located furthest from the penetration structure PS and vertically overlaps with the penetration structure PS.

The conductive pattern 19 may be located over the first stack ST1. The interlayer insulating layer 16 may be located over the conductive pattern 19. The metal pattern 15 may be located over the interlayer insulating layer 16. The interlayer insulating layer 16 may be located between the first stack ST1 and the metal pattern 15. The conductive pattern 19 may include polysilicon. The metal pattern 15 may include tungsten, molybdenum, copper, aluminum, or the like. The interlayer insulating layer 16 may include an insulating material such as oxide or nitride. As an example, the interlayer insulating layer 16 may include tetra ethyl ortho silicate (TEOS).

The penetration structure PS may include an air gap AG, and may further include a single layer or a multilayer layer. Referring to FIG. 1A, the penetration structure PS may include an insulating liner 17 and an air gap AG located inside the insulating liner 17. The air gap AG may be defined by the insulating liner 17, and an inner surface of the insulating liner 17 may be exposed through the air gap AG. An upper surface of the insulating liner 17 may be in contact with the interlayer insulating layer 16, and the insulating liner 17 and the interlayer insulating layer 16 may be a layer that is integrally connected. As an example, the insulating liner 17 and the interlayer insulating layer 16 may be one layer formed by the same process.

Referring to FIG. 1B, the penetration structure PS may include an insulating liner 17 and an air gap AG located in the insulating liner 17. The penetration structure PS may protrude from an upper surface of the first stack ST1, and may penetrate through the interlayer insulating layer 16. An upper surface of the penetration structure PS may be in contact with the metal pattern 15. The air gap AG may be defined by the insulating liner 17 and the metal pattern 15. An inner surface of the insulating liner 17 and a lower surface of the metal pattern 15 may be exposed through the air gap AG. The air gap AG may be sealed by the metal pattern 15.

Referring to FIG. 1C, the penetration structure PS may include a metal liner 18, an insulating liner 17 surrounding the metal liner 18, and an air gap AG located inside the metal liner 18. The penetration structure PS may protrude from an upper surface of the first stack ST1. The metal liner 18 may extend in the vertical direction through the first stack ST1, and may protrude from the upper surface of the first stack ST1. The air gap AG may be defined by the metal liner 18, and an inner surface of the metal liner 18 may be exposed through the air gap AG. The metal liner 18 may be in contact with the metal pattern 15.

Referring to FIG. 1D, the penetration structure PS may include a metal liner 18, an insulating liner 17 surrounding the metal liner 18, and an air gap AG located in the metal liner 18. The air gap AG may be defined by the metal liner 18 and the metal pattern 15, and an inner surface of the metal liner 18 and a lower surface of the metal pattern 15 may be exposed through the air gap AG.

Referring to FIG. 1E, the penetration structure PS may include a metal liner 18, a first insulating liner 17A surrounding the metal liner 18, a second insulating liner 17B located between the metal liner 18 and the first insulating liner 17A, and an air gap AG located in the metal liner 18. The first insulating liner 17A and the second insulating liner 17B may be layers formed by separate processes, and an interface between the layers may or might not be confirmed. The second insulating liner 17B may have a greater height than the first insulating liner 17A.

The interlayer insulating layer 16 may include a first interlayer insulating layer 16A and a second interlayer insulating layer 16B. The first interlayer insulating layer 16A and the second interlayer insulating layer 16B may be layers formed by separate processes, and an interface between the layers may or might not be confirmed. The first insulating liner 17A and the first interlayer insulating layer 16A may be formed as a single layer that is integrally formed, and the second insulating liner 17B and the second interlayer insulating layer 16B may be a single layer that is integrally formed.

According to the structure described above, the penetration structure PS including the air gap AG may extend through the first stack ST1. The second stack ST2 may include the key pattern K located to correspond to the penetration structure PS. The penetration structure PS may be located in a scribe lane region or located at an edge of a semiconductor chip.

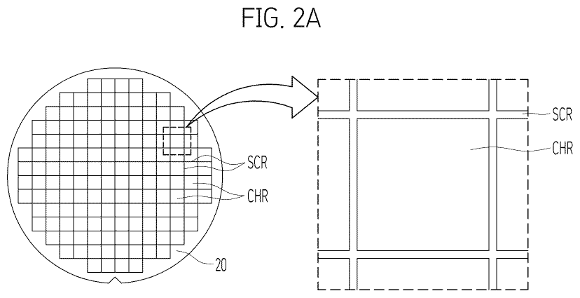

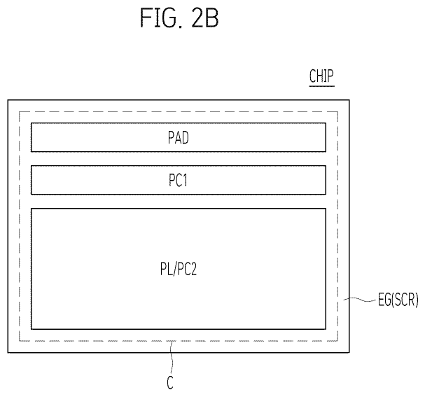

FIGS. 2A and 2B are diagrams illustrating the structure of a semiconductor device in accordance with an embodiment.

Referring to FIG. 2A, the semiconductor device may be a wafer 20, and the wafer may include chip regions CHR and a scribe lane region SCR. The scribe lane region SCR is a region where a cutting process is performed, and is located between the chip regions CHR. The chip regions CHR are regions corresponding to semiconductor chips. The first and second stacks ST1 and ST2 described above may be located in the chip regions CHR and the scribe lane region SCR, and the penetration structure PS may be located in the scribe lane region SCR.

Referring to FIG. 2B, the semiconductor device may be a semiconductor chip CHIP, and may include an internal region C and an edge region EG. The semiconductor chip CHIP may include a pad PAD, a first peripheral circuit PC1, a second peripheral circuit PC2, and a memory plane PL located in the internal region C. The first peripheral circuit PC1 may include a logic circuit, a data path circuit, an analog circuit, and the like, and the second peripheral circuit PC2 may include a page buffer, a row decoder, and the like. The memory plane PL and the second peripheral circuit PC2 may be stacked vertically.

Most of the scribe lane region SCR included in the wafer 20 is lost by the cutting process, but the scribe lane region SCR may remain at a perimeter of the chip region CHR. That is, the edge region EG of the semiconductor chip CHIP may be the remaining scribe lane region SCR. The penetration structure PS described above may be located in the edge region EG of the semiconductor chip CHIP.

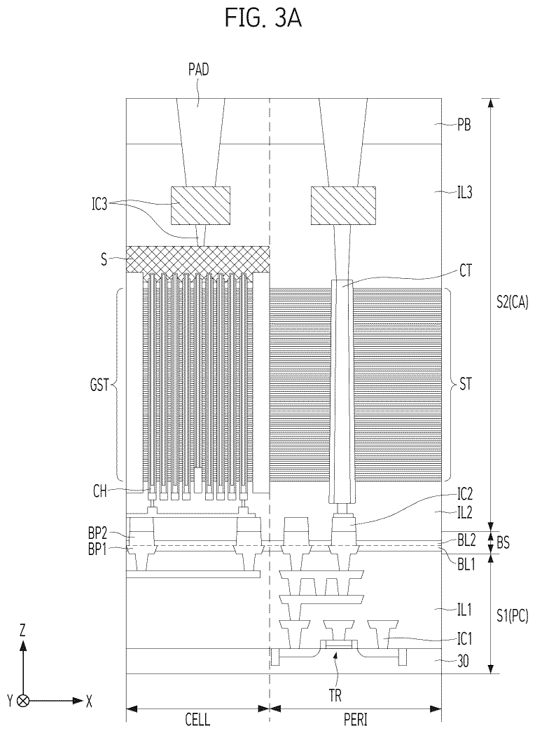

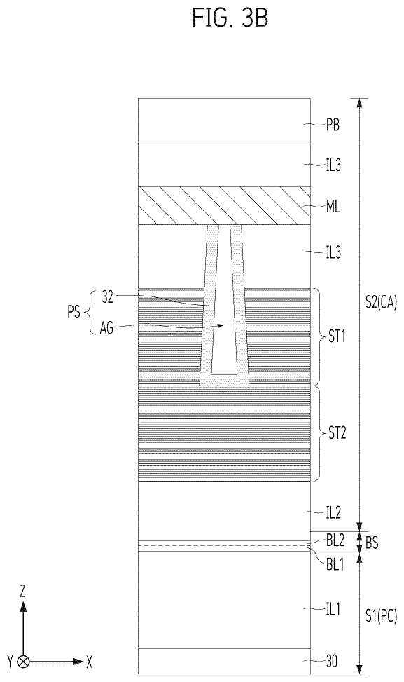

FIGS. 3A and 3B are diagrams illustrating the structure of a semiconductor device in accordance with an embodiment. FIG. 3A is a cross-sectional view of an internal region of a semiconductor chip, and illustrates a cell region CELL where memory cells are located and a peripheral region PERI where a peripheral circuit is located. FIG. 3B is a cross-sectional view of an edge of a semiconductor chip. Hereinafter, the content overlapping with the previously described content may be omitted.

Referring to FIGS. 3A and 3B, the semiconductor device may include a first semiconductor structure S1, a second semiconductor structure S2, and a bonding structure BS. The first semiconductor structure S1 may include a peripheral circuit PC (i.e., S1(PC)), and the second semiconductor structure S2 may include a memory cell array CA (i.e., S2(CA)).

The first semiconductor structure S1 may include a substrate 30, a transistor TR, a first interlayer insulating layer IL1, and a first interconnection structure IC1. The transistor TR may be located inside the semiconductor chip, and may belong to the peripheral circuit PC. As an example, the transistor TR may belong to a logic circuit, a data path circuit, an analog circuit, a page buffer, a row decoder, or the like. The first interconnection structure IC1 may be located in the first interlayer insulating layer IL1, and may include a via, a wiring line, and the like. The first interconnection structure IC1 may be electrically connected to the peripheral circuit PC.

The second semiconductor structure S2 may include a gate structure GST, a channel structure CH, a first stack ST1, a second stack ST2, a source layer S, a second interlayer insulating layer IL2, a second interconnection structure IC2, a third interlayer insulating layer IL3, a third interconnection structure IC3, a passivation layer PB, and a pad PAD. The gate structure GST may be located in the internal region of the semiconductor chip, and the first and second stacks ST1 and ST2 may be located in the internal region and the edge of the semiconductor chip.

The gate structure GST may include stacked gate lines, which may be a source select line, word lines, or a drain select line. A stack ST, the first stack ST1, and the second stack ST2 may include stacked insulating layers. The gate structure GST and the stack ST may be located at a level corresponding to the first and second stacks ST1 and ST2.

The source layer S may be located over the gate structure GST. The channel structure CH may extend through the gate structure GST, and may be connected to the source layer S. A wiring line of the second interconnection structure IC2 connected to the channel structure CH may be a bit line.

A contact plug CT may be located inside the semiconductor chip, and may be located in the peripheral region PERI. The contact plug CT may penetrate through the stack ST. The second interconnection structure IC2 and the third interconnection structure IC3 may be electrically connected to each other through the contact plug CT. As an example, the contact plug CT may be electrically connected to the peripheral circuit such as a page buffer and a row decoder.

The third interlayer insulating layer IL3 may be located over the source layer S. The third interconnection structure IC3 may be located inside the third interlayer insulating layer IL3, and may be electrically connected to the source layer S, the contact plug CT, and the like.

A metal pattern ML may be located over the first and second stacks ST1 and ST2, and may be located in the third interlayer insulating layer IL3. The metal pattern ML may be located at the same level as a wiring line included in the third interconnection structure IC3.

A penetration structure PS may extend through the first stack ST1, and may extend into the third interlayer insulating layer IL3. The penetration structure PS may be in contact with the metal pattern ML. The penetration structure PS may include a liner layer 32 and an air gap AG located inside the liner layer 32. The air gap AG may be sealed by the metal pattern ML. The liner layer 32 may include oxide, metal, or the like, and may be a single layer or a multilayer layer.

The passivation layer PB may be located over the third interlayer insulating layer IL3. The passivation layer PB may include an oxide layer formed by a high density plasma (HDP) method. The pad PAD may extend through the passivation layer PB and the third interlayer insulating layer IL3, and may be electrically connected to the third interconnection structure IC3.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array CA including the gate structure GST and the peripheral circuit PC may be electrically connected to each other by the bonding structure BS.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include SiCN, tetra ethyl ortho silicate (TEOS), or the like. The first bonding pad BP1 may be electrically connected to the first interconnection structure IC1, and the second bonding pad BP2 may be electrically connected to the second interconnection structure IC2. The memory cell array CA and the peripheral circuit PC may be electrically connected to each other through the first bonding pad BP1 and the second bonding pad BP2.

According to an embodiment of the structures described above, the penetration structure PS may be located at the edge of the semiconductor chip. In an embodiment, the penetration structure PS may have a greater width in the horizontal direction and/or a greater height in the vertical direction than the channel structure CH, and may include the air gap AG therein. In an embodiment, the penetration structure PS may be in contact with the metal pattern ML, and the air gap AG may be sealed by the metal pattern ML.

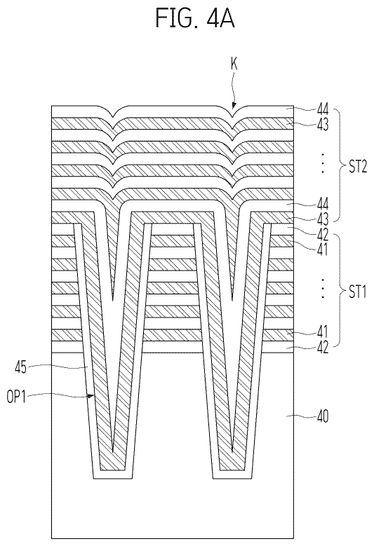

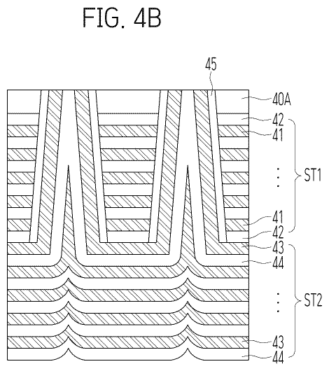

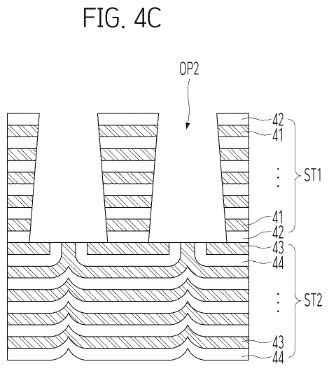

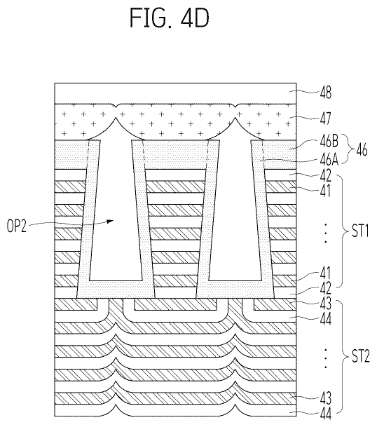

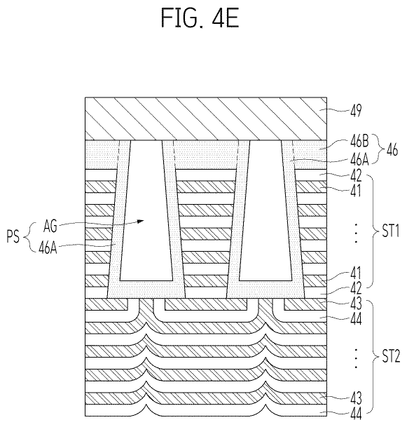

FIGS. 4A to 4E are diagrams for describing a manufacturing method of a semiconductor device in accordance with an embodiment. Hereinafter, the content overlapping with the previously described content may be omitted.

Referring to FIG. 4A, a first stack ST1 is formed on a substrate 40. The first stack ST1 may include first material layers 41 and second material layers 42 that are alternately stacked. The first material layers 41 may each include a material having a high etching selectivity with respect to the second material layers 42. As an example, the first material layers 41 may each include an insulating material such as nitride, and the second material layers 42 may each include an insulating material such as oxide. The first material layers 41 may each include a conductive material such as polysilicon, tungsten, or molybdenum, and the second material layers 42 may each include an insulating material such as oxide.

Subsequently, a first opening OP1 extending into the substrate 40 through the first stack ST1 is formed. The first opening OP1 may have a tapered shape, and may have a smaller width at a lower portion thereof than at an upper portion thereof. The first opening OP1 may be located in a scribe lane region.

Subsequently, a sacrificial layer 45 is formed in the first opening OP1. The sacrificial layer 45 may be conformally formed along an inner surface of the first opening OP1. The sacrificial layer 45 may include a material having a high etching selectivity with respect to the first and second material layers 41 and 42. As an example, the sacrificial layer 45 may include tungsten.

Subsequently, a second stack ST2 is formed on the first stack ST1. The second stack ST2 may include third material layers 43 and fourth material layers 44 that are alternately stacked. The third material layers 43 may each include a material having a high etching selectivity with respect to the fourth material layers 44. As an example, the third material layers 43 may each include an insulating material such as nitride, and the fourth material layers 44 may each include an insulating material such as oxide. The third material layers 43 may each include a conductive material such as polysilicon, tungsten, or molybdenum, and the fourth material layers 44 may each include an insulating material such as oxide.

The second stack ST2 may be formed to fill the first opening OP1. The third and fourth material layers 43 and 44 may be formed along a surface of the sacrificial layer 45, and may be stacked in a shape in which they are recessed into the first opening OP1. Accordingly, an upper surface of the second stack ST2 may include a groove due to a recessed region, and the groove may be a key pattern K. Through this, the key pattern K transferred from the first opening OP1 may be formed. As an example, the key pattern K may be located in the scribe lane region, and may be used as an alignment key or an overlay key when a channel hole is formed. Here, in an embodiment, the alignment key is used to satisfy a minimum condition for aligning patterns with each other, and may be used to relatively roughly align the patterns with each other. In an embodiment, the overlay key may be used to finely align patterns with each other in units of several tens of nanometers.

Referring to FIG. 4B, the substrate 40 is etched so that the sacrificial layer 45 is exposed. As an example, the sacrificial layer 45 may be exposed by etching a rear surface of the substrate 40 using a grinding process and/or a planarization process. The planarization process may be a chemical mechanical polish (CMP) process.

Referring to FIG. 4C, a second opening OP2 is formed by removing the sacrificial layer 45. Metal particles in the second opening OP2 may be removed using a cleaning process. The third and fourth material layers 43 and 44 formed in the second opening OP2 may be etched. In this process, the first and second material layers 41 and 42 may also be partially etched. The second opening OP2 may be substantially the same as the first opening OP1 or may be greater than the first opening OP1.

Subsequently, the remaining substrate 40A may be removed. As an example, the substrate 40A may be etched using a wet etching process.

Referring to FIG. 4D, an insulating layer 46 is formed on the first stack ST1. The insulating layer 46 may be conformally formed along a surface of the first stack ST1 including the second opening OP2. The insulating layer 46 may partially fill the second opening OP2. The insulating layer 46 may include an insulating liner 46A formed along an inner surface of the second opening OP2 and an interlayer insulating layer 46B formed above the first stack ST1.

Subsequently, a hard mask layer 47 is formed on the insulating layer 46. The hard mask layer 47 may be formed on the first stack ST1 to have an overhang structure above the insulating liner 46A. In an embodiment, the hard mask layer 47 may be formed by a deposition method having poor step coverage. In such a case, the second opening OP2 may be sealed by a hard mask material deposited on the insulating layer 46 above the first stack ST1, and the hard mask layer 47 having the overhang structure may be formed.

Subsequently, a mask pattern 48 may be formed on the hard mask layer 47. The mask pattern 48 may be used to form a contact hole in a cell region and/or a peripheral region, and may cover the scribe lane region. When the mask pattern 48 is formed on the insulating layer 46 without the hard mask layer 47, the mask pattern 48 may be recessed into the second opening, which may cause a step on an upper surface of the mask pattern 48. Accordingly, in an embodiment, by sealing the second opening OP2 with the hard mask layer 47 and then forming the mask pattern 48, it is possible to form the mask pattern 48 without a step.

Subsequently, the hard mask layer 47 may be etched using the mask pattern 48 as an etching barrier. In an embodiment, because the mask pattern 48 that does not have the step covers the scribe lane region, the hard mask layer 47 formed above the second opening OP2 might not be etched in a process of etching the insulating layer 46 using the mask pattern 48 as an etching barrier. Accordingly, in an embodiment, it is possible to prevent or mitigate the insulating layer 46 in the second opening OP2 from being etched and prevent or mitigate an abnormal pattern from being caused. Subsequently, the mask pattern 48 and the hard mask layer 47 may be removed, and the second opening OP2 may be reopened.

Referring to FIG. 4E, a metal pattern 49 is formed above the first stack ST1. The metal pattern 49 may be formed on the insulating layer 46. The second opening OP2 may be sealed by the metal pattern 49, and an air gap AG may be defined in the second opening OP2. Through this, a penetration structure PS including the insulating liner 46A and the air gap AG located in the insulating liner 46A may be formed.

According to an embodiment of the manufacturing methods described above, the key pattern K may be formed in the scribe lane region. In an embodiment, it is possible to prevent or mitigate the insulating layer 46 in the second opening OP2 from being lost and it is possible to prevent or mitigate an abnormal pattern from being formed, using the hard mask layer 47 having the overhang structure.

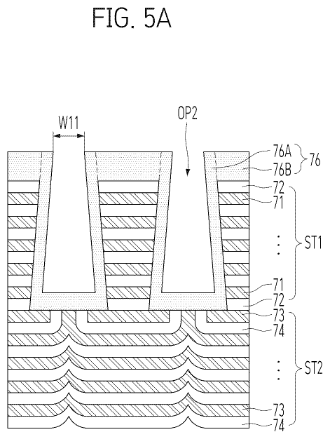

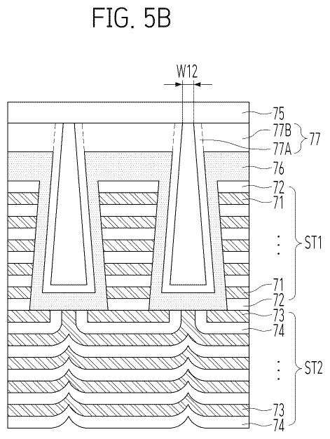

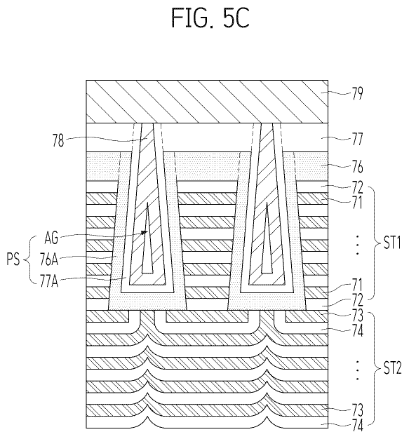

FIGS. 5A to 5C are diagrams for describing a manufacturing method of a semiconductor device in accordance with an embodiment. Hereinafter, the content overlapping with the previously described content may be omitted.

Referring to FIG. 5A, a second opening OP2 may be formed in a first stack ST1. The first stack ST1 may include first material layers 71 and second material layers 72 that are alternately stacked. A second stack ST2 may include third material layers 73 and fourth material layers 74 that are alternately stacked. Processes of forming the first stack ST1, the second stack ST2, and the second opening OP2 may be the same as those of an embodiment described above with reference to FIGS. 4A to 4C.

Subsequently, a first insulating layer 76 is formed on the first stack ST1. The first insulating layer 76 may be conformally formed along a surface of the first stack ST1 including the second opening OP2. The first insulating layer 76 may partially fill the second opening OP2. The first insulating layer 76 may include a first insulating liner 76A formed along an inner surface of the second opening OP2 and a first interlayer insulating layer 76B formed above the first stack ST1. As the first insulating layer 76 is formed, a width of the uppermost portion of the second opening OP2 is a first width W11.

Referring to FIG. 5B, a second insulating layer 77 is formed on the first insulating layer 76. The second insulating layer 77 may be conformally formed along a surface of the first insulating layer 76. The second insulating layer 77 may partially fill the second opening OP2. The second insulating layer 77 may include a second insulating liner 77A formed inside the second opening OP2 and a second interlayer insulating layer 77B formed above the first stack ST1. As the second insulating layer 77 is formed, the width of the uppermost portion of the second opening OP2 is reduced to a second width W12.

Subsequently, a mask pattern 75 is formed on the second insulating layer 77. The second opening OP2 may be sealed by the mask pattern 75. The mask pattern 75 may be used to form a contact hole in a cell region and/or a peripheral region, and may cover a scribe lane region. Because the width of the uppermost portion of the second opening OP2 is reduced to the second width W12 by the second insulating layer 77, the mask pattern 75 may be formed above the second opening OP2 without a step.

Subsequently, the second insulating layer 77 and the first insulating layer 76 may be etched using the mask pattern 75 as an etching barrier. Through this, the contact hole may be formed in the cell region and/or the peripheral region. Because the mask pattern 75 that does not have the step covers the scribe lane region, the first insulating layer 76 and the second insulating layer 77 formed inside the second opening OP2 are not etched. Subsequently, the mask pattern 75 may be removed, and the second opening OP2 may be reopened.

Referring to FIG. 5C, a metal liner 78 is formed on the second insulating layer 77. The metal liner 78 may be formed inside the second opening OP2. The second opening OP2 may be sealed by the metal liner 78, and an air gap AG may be defined in the metal liner 78. Through this process, a penetration structure PS including the first insulating liner 76A, the second insulating liner 77A, and the air gap AG may be formed. Subsequently, a metal pattern 79 is formed on the second insulating layer 77.

According to an embodiment of the manufacturing methods described above, by forming the insulating liner in a multilayer structure, it is possible to reduce the width of the uppermost portion of the second opening OP2. Accordingly, in an embodiment, even though the mask pattern 78 is formed without a hard mask layer, it is possible to form the mask pattern 78 without the step, and it is possible to prevent or mitigate an abnormal pattern from being formed.

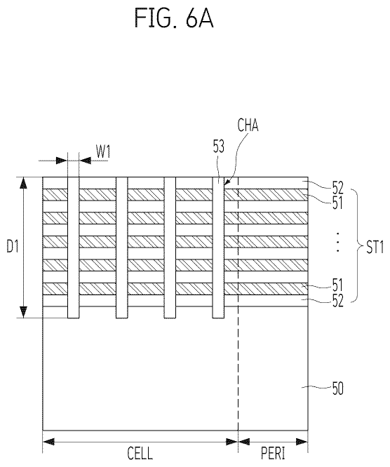

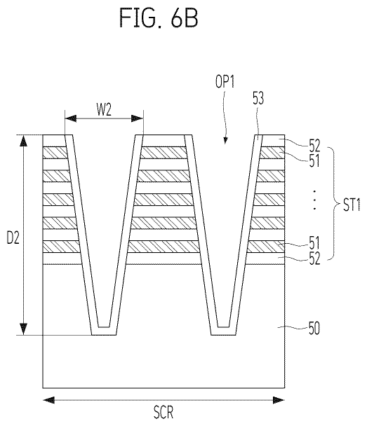

FIGS. 6A, 7A, 8A, 9A, 10A, 11A, 12A, 13A, 14A, 15A, 16A, and 17A and FIGS. 6B, 7B, 8B, 9B, 10B, 11B, 12B, 13B, 14B, 15B, 16B, and 17B are diagrams for describing a manufacturing method of a semiconductor device in accordance with an embodiment. FIGS. 6A, 7A, 8A, 9A, 10A, 11A, 12A, 13A, 14A, 15A, 16A, and 17A are cross-sectional views of a cell region CELL and a peripheral region PERI, and FIGS. 6B, 7B, 8B, 9B, 10B, 11B, 12B, 13B, 14B, 15B, 16B, and 17B are cross-sectional views of a scribe lane region.

Referring to FIGS. 6A and 6B, a first stack ST1 is formed on a substrate 50 including the cell region CELL, the peripheral region PERI, and the scribe lane region SCR. The first stack ST1 may be located in the cell region CELL, the peripheral region PERI, and the scribe lane region SCR. The first stack ST1 may include first material layers 51 and second material layers 52 that are alternately stacked.

Subsequently, a first channel hole CHA extending into the substrate 50 through the first stack ST1 may be formed. The first channel hole CHA may be located in the cell region CELL, and may have a first width W1 and a first depth D1.

A first opening OP1 extending into the substrate 50 through the first stack ST1 may be formed. The first opening OP1 may be located in the scribe lane region SCR, and may have a second width W2 greater than the first width W1 and a second depth D2 greater than the first depth D1. As an example, the first opening OP1 may have a tapered shape, and may have a smaller width at a lower portion thereof than at an upper portion thereof. A minimum width of the first opening OP1 may be greater than the first width W1.

The first channel hole CHA and the first opening OP1 may be formed simultaneously. By simultaneously forming the first opening OP1 having a relatively great width W2 and the first channel hole CHA having a relatively small width W1, the first opening OP1 may be formed at a greater depth than the first channel hole CHA. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Subsequently, a sacrificial layer 53 may be formed in the first channel hole CHA. As an example, a sacrificial material layer may be formed on the first stack ST1 including the first channel hole CHA, and may be planarized so that an upper surface of the first stack ST1 is exposed. Through this, the sacrificial layer 53 filling the first channel hole CHA may be formed. The sacrificial layer 53 may include a material having a high etching selectivity with respect to the first and second material layers 51 and 52. The sacrificial layer 53 may include tungsten.

A sacrificial layer 53 may be formed in the first opening OP1. The sacrificial layer 53 may be conformally formed along an inner surface of the first opening OP1. It is possible to form the sacrificial layer 53 in the first channel hole CHA while forming the sacrificial layer 53 in the first opening OP1. Because the first opening OP1 has a greater size than the first channel hole CHA, the first channel hole CHA may be completely filled with the sacrificial layer 53, and the first opening OP1 may be only partially filled with the sacrificial layer 53.

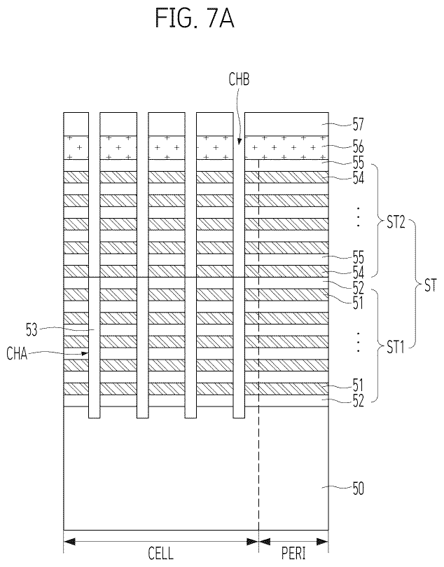

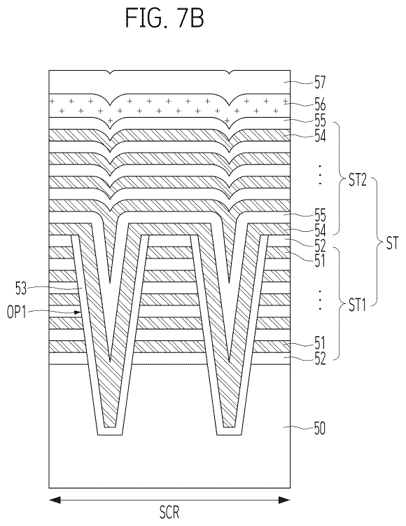

Referring to FIGS. 7A and 7B, a second stack ST2 is formed above the first stack ST1. The second stack ST2 may include third material layers 54 and fourth material layers 55 that are alternately stacked. In the scribe lane region SCR, the third and fourth material layers 54 and 55 may be formed in the first opening OP1. The third and fourth material layers 54 and 55 may be stacked along a surface of the sacrificial layer 53. The third and fourth material layers 54 and 55 may be stacked in a shape in which they are recessed into the first opening OP1, and an upper surface of the second stack ST2 may include a groove located in a recessed region.

Subsequently, a hard mask layer 56 may be formed above the second stack ST2, and a mask pattern 57 may be formed above the hard mask layer 56. The mask pattern 57 may include an opening located in the cell region CELL, and may cover the peripheral region PERI and the scribe lane region SCR. When the mask pattern 57 is formed, a key pattern K may be used as an alignment key or an overlay key.

Subsequently, the hard mask layer 56 may be etched using the mask pattern 57 as an etching barrier. Subsequently, the second stack ST2 may be etched using the hard mask layer 56 as an etching barrier. Through this, a second channel hole CHB extending through the second stack ST2 may be formed. The second channel hole CHB may be connected to the first channel hole CHA, and may expose the sacrificial layer 53. Subsequently, the mask pattern 57 and the hard mask layer 56 may be removed.

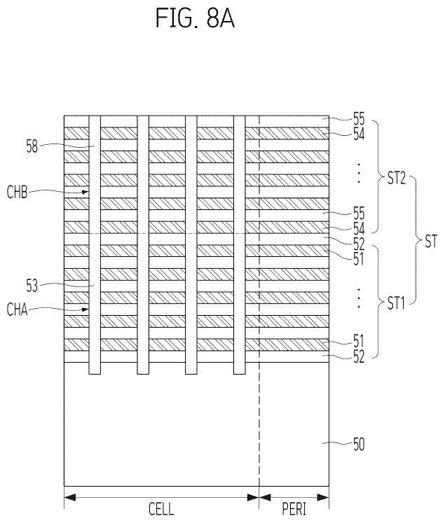

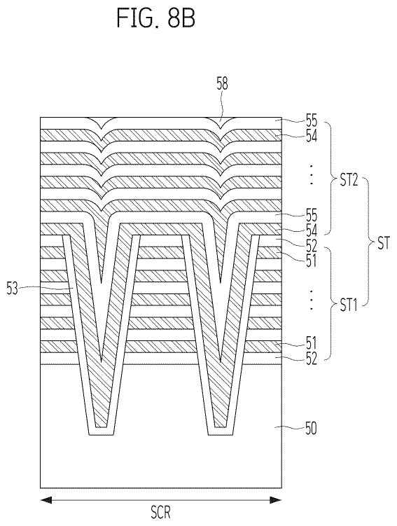

Referring to FIGS. 8A and 8B, a sacrificial layer 58 may be formed in the second channel hole CHB. A sacrificial material layer may be formed on the second stack ST2, and may be planarized so that the upper surface of the second stack ST2 is exposed. Through this, the sacrificial layer 58 filling the second channel hole CHB may be formed. The sacrificial layer 58 may include a material having a high etching selectivity with respect to the third material layers 54 and the fourth material layers 55. The sacrificial layer 58 may include tungsten.

In the scribe lane region SCR, the upper surface of the second stack ST2 may include a groove, and the sacrificial layer 58 may be filled in the groove. In an embodiment, the groove may be formed by a concave portion of the material layer and may be filled with the sacrificial layer 58.

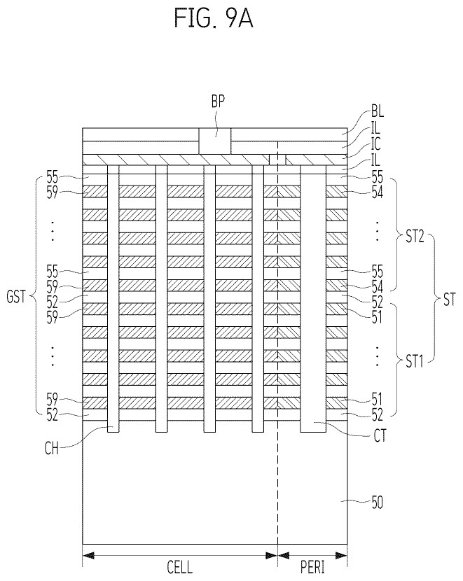

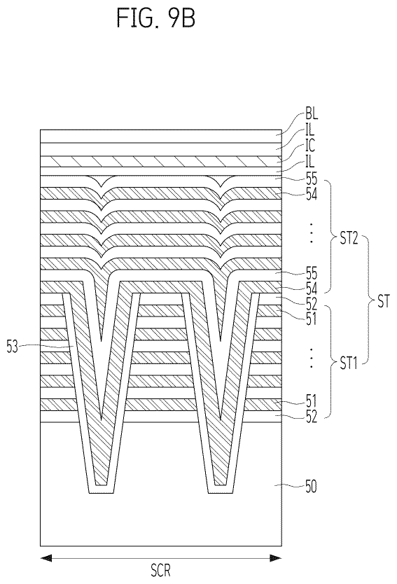

Referring to FIGS. 9A and 9B, the first channel hole CHA and the second channel hole CHB may be reopened by removing the sacrificial layer 53 and the sacrificial layer 58. Subsequently, a channel structure CH may be formed in the reopened first and second channel holes CHA and CHB. The channel structure CH may include a channel layer, a memory layer surrounding sidewalls of the channel layer, and an insulating core located in the channel layer. The memory layer may include at least one of a tunneling layer, a data storage layer, and a blocking layer. The data storage layer may include a floating gate, polysilicon, a charge trap material, nitride, a variable resistance material, or the like.

Subsequently, the first material layers 51 and the third material layers 54 may be replaced with conductive layers 59. Portions of the first and third material layers 51 and 54 located in the cell region CELL may be replaced with the conductive layers 59. Through this, a gate structure GST including the conductive layers 59 and insulating layers 52 and 55 that are alternately stacked may be formed in the cell region CELL. The first material layers 51 of the peripheral region PERI and the scribe lane region SCR may remain without being replaced with the conductive layer 59. Through this, a stack ST including first insulating layers 51 and 54 and second insulating layers 52 and 55 that are alternately stacked may be formed in the peripheral region PERI and the scribe lane region SCR.

Subsequently, a contact plug CT extending into the substrate 50 through the second stack ST2 and the first stack ST1 may be formed. The contact plug CT may be formed in the peripheral region PERI. The contact plug CT may have a greater width than the channel structure CH.

Subsequently, an interconnection structure IC, an interlayer insulating layer IL, a bonding layer BL, and a bonding pad BP may be formed on the second stack ST2. In the cell region CELL, the interconnection structure IC may be connected to the channel structure CH. In the peripheral region PERI, the interconnection structure IC may be electrically connected to the contact plug CT. In the scribe lane region SCR, the interconnection structure IC may be located over the second stack ST2.

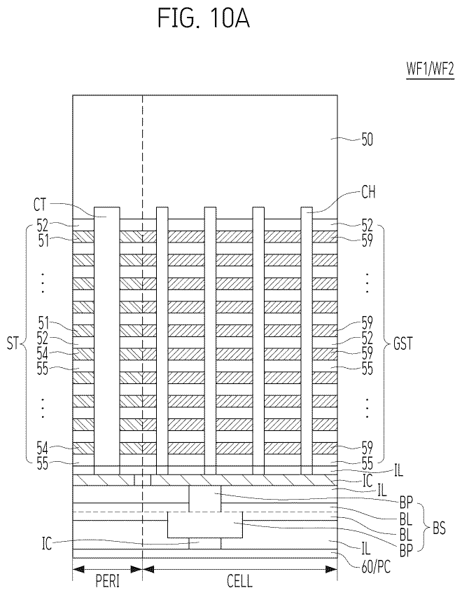

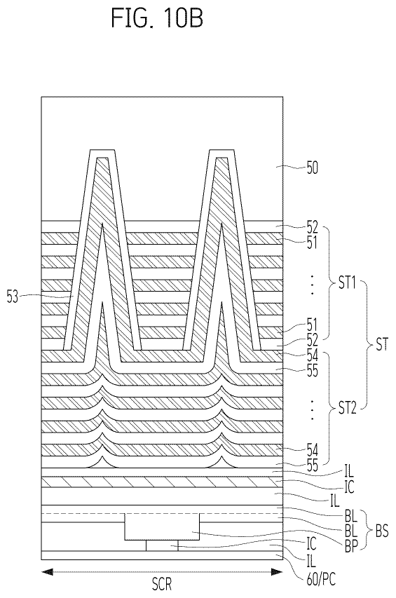

Referring to FIGS. 10A and 10B, a second wafer WF2 including a substrate 60, a peripheral circuit PC, an interconnection structure IC electrically connected to the peripheral circuit PC, an interlayer insulating layer IL, a bonding layer BL, and a bonding pad BP is formed. Subsequently, a first wafer WF1 may be inverted so that the substrate 50 is located over the stack ST and the gate structure GST, and the inverted first wafer WF1 and the second wafer WF2 may be bonded to each other. Through this, the first wafer WF1 including the gate structure GST, the channel structure CH, the stack ST, and the sacrificial layer 53 and the second wafer WF2 including the peripheral circuit PC may be bonded to each other. The interconnection structure IC of the first wafer WF1 and the interconnection structure IC of the second wafer WF2 may be electrically connected to each other through the bonding pads BP.

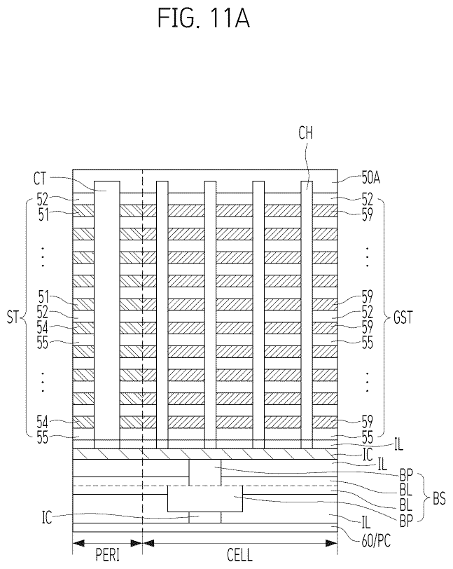

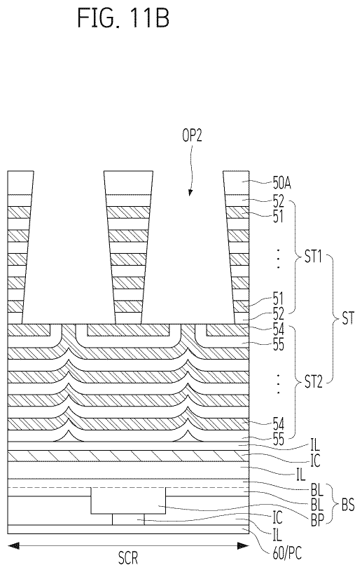

Referring to FIGS. 11A and 11B, the sacrificial layer 53 is exposed by etching the substrate 50. As an example, the sacrificial layer 53 may be exposed by etching a rear surface of the substrate 50 using a grinding process and/or a planarization process. The etched substrate 50A may cover the channel structure CH, and the channel structure CH is not exposed.

Subsequently, a second opening OP2 is formed by removing the sacrificial layer 53. A portion of the second stack ST2 formed in the first opening OP1 may be etched. In this process, the first stack ST1 may also be partially etched. The second opening OP2 may have a size that is the same as or greater than that of the first opening OP1. Subsequently, the remaining substrate 50A is removed. The substrate 50A may be removed using a wet etching process. Through this, the channel structure CH and the contact plug CT may be exposed. Subsequently, the memory layer of the channel structure CH may be etched to expose the channel layer, and the channel layer may be doped with impurities.

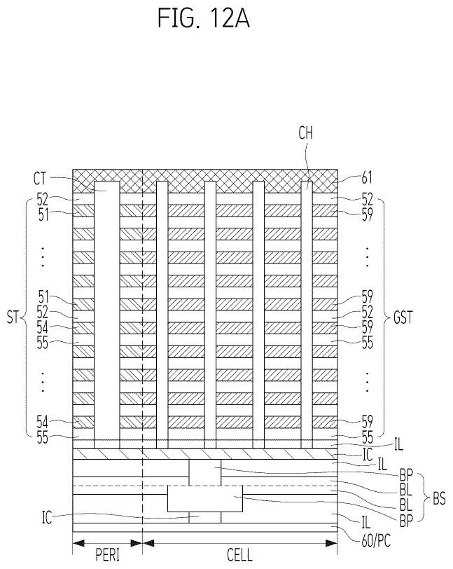

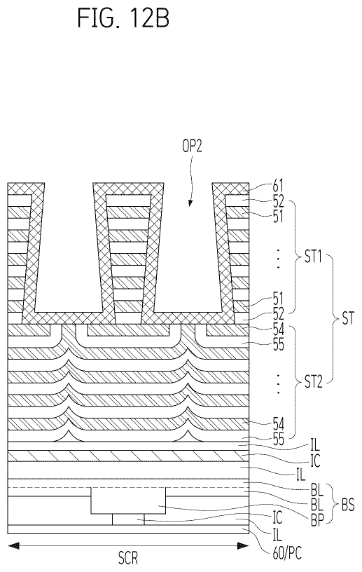

Referring to FIGS. 12A and 12B, a source conductive layer 61 may be formed above the first stack ST1. The source conductive layer 61 may be formed along a surface of the first stack ST1 including the second opening OP2 using a deposition process. The source conductive layer 61 may include polysilicon. In the cell region CELL, the source conductive layer 61 may be formed on the gate structure GST, and may be connected to the channel structure CH. In the peripheral region PERI, the source conductive layer 61 may be formed on the first stack ST1, and may be connected to the contact plug CT. In the scribe lane region SCR, the source conductive layer 61 may be formed on the first stack ST1, and may extend along an inner surface of the second opening OP2.

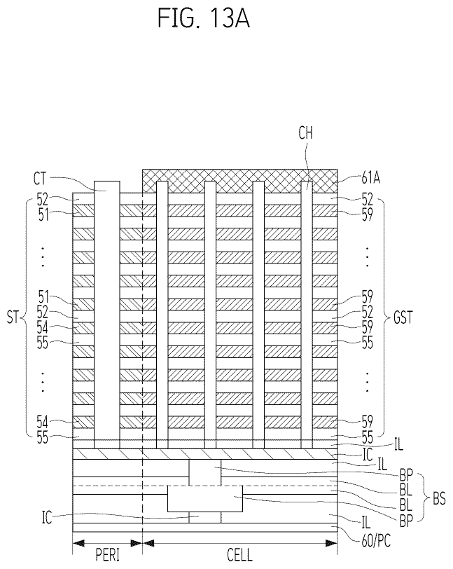

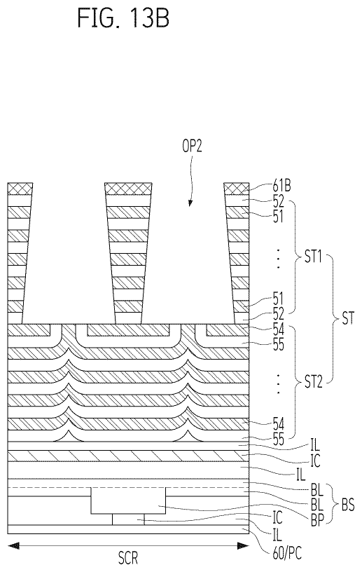

Referring to FIGS. 13A and 13B, a source layer 61A may be formed by etching the source conductive layer 61. As an example, the source conductive layer 61 may be patterned using a mask pattern. The source layer 61A may be formed in the cell region CELL, and may be connected to the channel structure CH. In the peripheral region PERI, the source conductive layer 61 may be removed, and the contact plug CT may be exposed. In the scribe lane region SCR, a portion of the source conductive layer 61 formed inside the second opening OP2 may be etched, and a conductive pattern 61B may be formed on the upper surface of the first stack ST1.

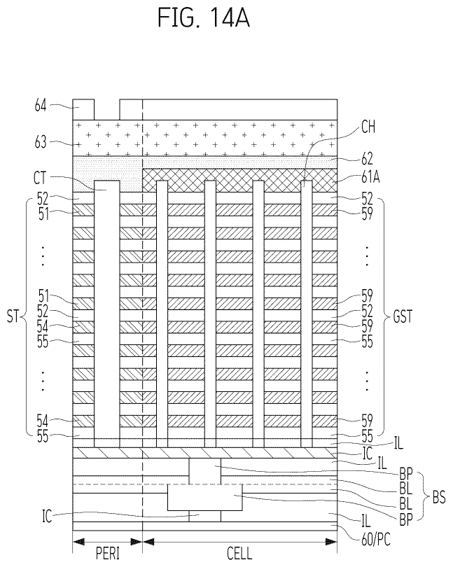

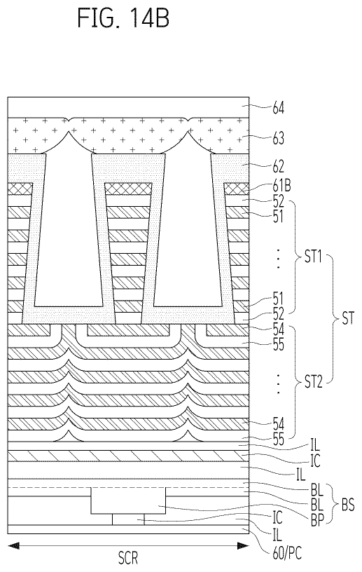

Referring to FIGS. 14A and 14B, an insulating layer 62 is formed along the surface of the first stack ST1 including the second opening OP2. In the cell region CELL, the insulating layer 62 may be formed above the source layer 61A. In the peripheral region PERI, the insulating layer 62 may be formed above the first stack ST1, and may surround the contact plug CT protruding from the surface of the first stack ST1. In the scribe lane region SCR, the insulating layer 62 may be conformally formed along a surface of the conductive pattern 61B and the inner surface of the second opening OP2. The insulating layer 62 may or might not seal the second opening OP2. The insulating layer 62 may include an insulating material such as oxide or nitride.

Subsequently, a hard mask layer 63 is formed above the first stack ST1. The hard mask layer 63 may be formed on the insulating layer 62, and may have an overhang structure above the second opening OP2. By depositing a hard mask material by a method having poor step coverage to seal the second opening OP2, it is possible to form the hard mask layer 63 having the overhang structure. The hard mask layer 63 may include carbon. For reference, it is also possible to form a second insulating layer on the insulating layer 62 as described above with reference to FIG. 5B, instead of forming the hard mask layer 63.

Subsequently, a mask pattern 64 may be formed on the hard mask layer 63. The mask pattern 64 may include an opening corresponding to the contact plug CT, and may cover the cell region CELL and the scribe lane region SCR. Because the mask pattern 64 is formed on the hard mask layer 63 having the overhang structure in the scribe lane region SCR, the mask pattern 64 may have a flat upper surface.

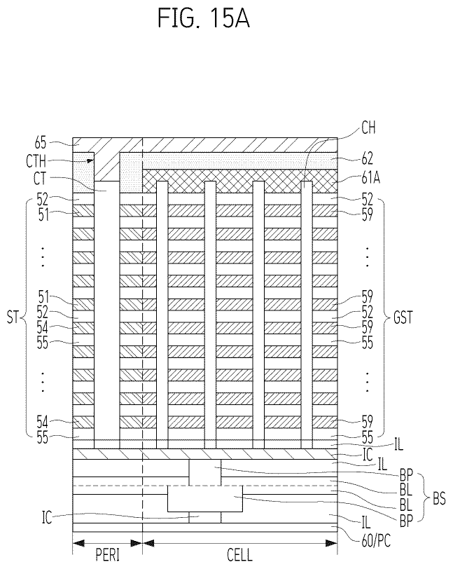

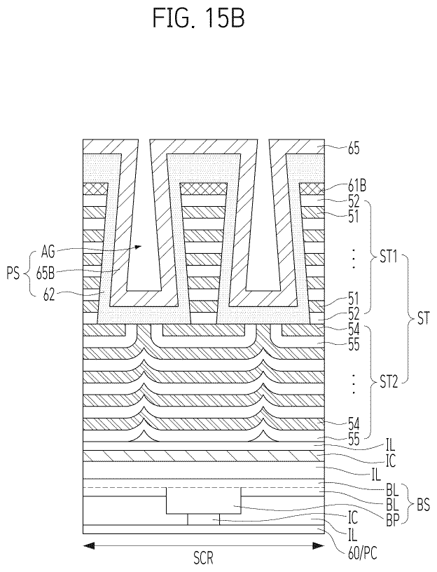

Referring to FIGS. 15A and 15B, the hard mask layer 63 is etched using the mask pattern 64 as an etching barrier. Subsequently, a contact hole CTH may be formed by etching the insulating layer 62 using the etched hard mask layer 63 as an etching barrier. In the scribe lane region SCR, in an embodiment, the flat mask pattern 64 has been formed on the hard mask layer 63 having the overhang structure, and it is thus possible to prevent or mitigate the insulating layer 62 in the second opening OP2 from being etched and prevent or mitigate an abnormal pattern from being formed in a process of forming the contact hole CTH.

For reference, when the mask pattern 64 is formed without forming the hard mask layer 63 having the overhang structure, the mask pattern 64 may be recessed into the second opening OP2, and the upper surface of the mask pattern 64 may have a step. For this reason, in the process of forming the contact hole CTH, the insulating layer 62 inside the second opening OP2 may be etched, and the abnormal pattern may be formed. According to an embodiment of the present disclosure, it is possible to prevent or reduce the formation of the abnormal pattern.

Subsequently, the mask pattern 64 and the hard mask layer 63 may be removed, and a via conductive layer 65 may be formed above the insulating layer 62. In the peripheral region PERI, the via conductive layer 65 may fill the contact hole CTH. In the scribe lane region SCR, a via conductive layer 65 may be formed on the insulating layer 62, and may extend into the second opening OP2. The second opening OP2 might not be completely filled with the via conductive layer 65. The second opening OP2 may or might not be sealed by the via conductive layer 65. For reference, when the second opening OP2 is sealed by the insulating layer 62, the via conductive layer 65 might not be formed in the second opening OP2. The via conductive layer 65 may include metal such as tungsten.

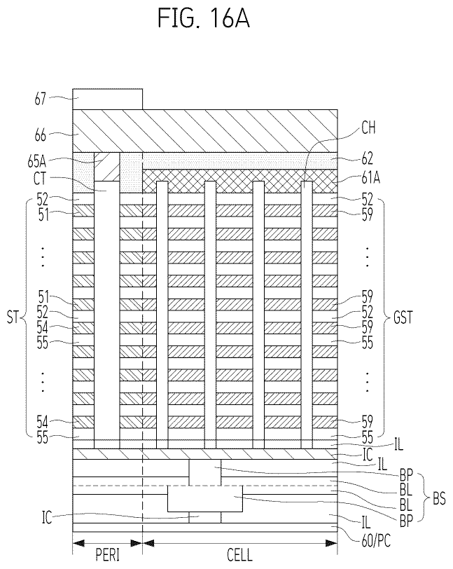

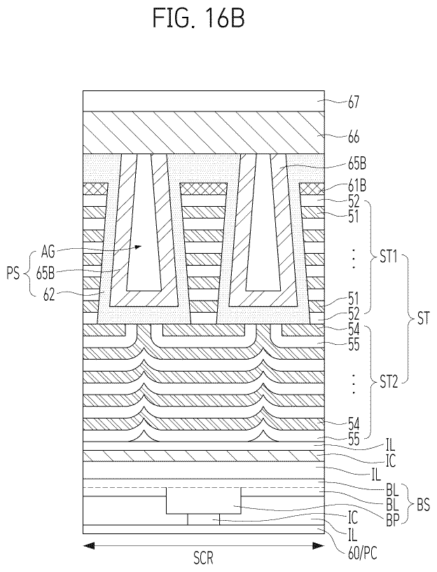

Referring to FIGS. 16A and 16B, a via 65A is formed in the contact hole CTH by etching the via conductive layer 65. A metal liner 65B may be formed in the second opening OP2 by etching the via conductive layer 65. The via 65A and the metal liner 65B may be formed simultaneously. As an example, the via 65A and the metal liner 65B may be formed by polishing the via conductive layer 65 using a planarization process.

Subsequently, a metal layer 66 is formed above the insulating layer 62. As an example, the metal layer 66 may be formed using a deposition process. The metal layer 66 may be located over the metal liner 65B, and the second opening OP2 may be sealed by the metal layer 66. Through this, an air gap AG may be defined in the second opening OP2.

Subsequently, a mask pattern 67 may be formed above the metal layer 66. The mask pattern 67 may be used to form a metal wiring line connected to the via 65A. The mask pattern 67 may include an opening exposing the cell region CELL, and may cover a portion of the peripheral region PERI and the scribe lane region SCR.

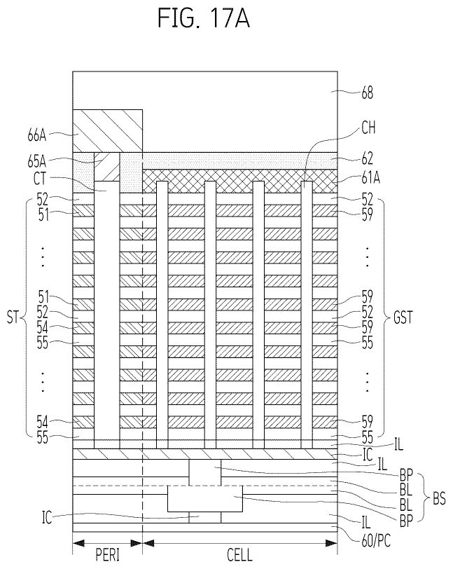

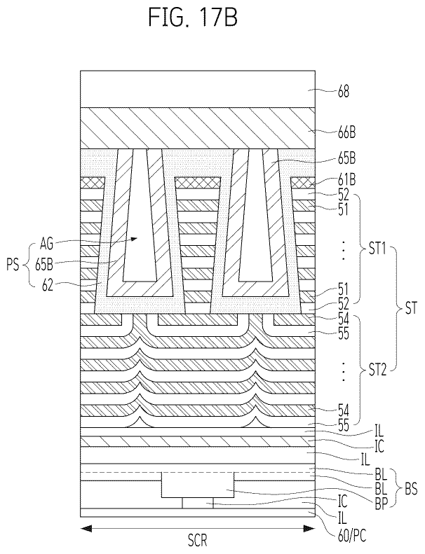

Referring to FIGS. 17A and 17B, the metal layer 66 is etched using the mask pattern 67 as an etching barrier. A metal wiring line 66A may be formed in the peripheral region PERI by etching the metal layer 66. The metal wiring line 66A may be electrically connected to the via 65A. A metal pattern 66B may be formed in the scribe lane region SCR by etching the metal layer 66. The metal pattern 66B may seal the air gap AG located inside the metal liner 65B. Through this, a penetration structure PS including the insulating layer 62, the metal liner 65B, and the air gap AG may be formed.

Subsequently, an interlayer insulating layer 68 may be formed on the metal wiring line 66A and the metal pattern 66B. The interlayer insulating layer 68 may include an insulating material such as oxide or nitride.

According to an embodiment of the manufacturing methods described above, manufacturing processes of the cell region CELL, the peripheral region PERI, and the scribe lane region SCR may be performed together. The first channel hole CHA of the cell region CELL and the first opening OP1 of the scribe lane region SCR may be formed simultaneously. The via 65A of the peripheral region PERI and the metal liner 65B of the scribe lane region SCR may be formed simultaneously. The metal wiring line 66A of the peripheral region PERI and the metal pattern 66B of the scribe lane region SCR may be formed simultaneously. In am embodiment, because the hard mask layer 63 having the overhang structure is used, even though processes are performed simultaneously on different regions, it is possible to prevent or mitigate the abnormal pattern from being formed in the scribe lane region SCR.

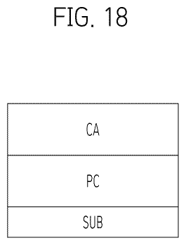

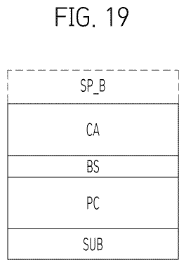

The structure and the manufacturing method according to the above-described embodiments may be applied to semiconductor devices of various structures. FIGS. 18 and 19 illustrate a schematic configuration of a semiconductor device to which the above-described embodiments are applicable.

FIG. 18 is a configuration diagram of a semiconductor device according to an embodiment of the present disclosure.

Referring to FIG. 18, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 19 is a configuration diagram of a semiconductor device according to an embodiment of the present disclosure.

Referring to FIG. 21, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, in an embodiment, contact plugs, lines, and the like formed on different wafers may be electrically connected without a separate bonding pad.

Other configurations may be equal or similar to those described above with reference to FIG. 18.

Meanwhile, the semiconductor device may have a structure in which the embodiments described above with reference to FIGS. 18 and 19 are combined or may have a partially modified structure. In the embodiment described with reference to FIGS. 18 and 19, positions of the memory cell array CA and the peripheral circuit PC may be changed. At least one memory cell array CA and/or at least one peripheral circuit PC may be additionally bonded to the embodiment described with reference to FIGS. 18 and 19. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a first stack including first insulating layers and second insulating layers, the first insulating layers are alternately stacked with the second insulating layers in a vertical direction;
a penetration structure extending in the vertical direction through the first stack and including an air gap; and
a second stack located under the first stack and including a key pattern located to overlap with the air gap in the vertical direction.

2. The semiconductor device of claim 1, wherein the penetration structure comprises:
an insulating liner; and
the air gap located inside the insulating liner.

3. The semiconductor device of claim 2, further comprising:
a metal pattern overlapping with the first stack in the vertical direction; and
an interlayer insulating layer located between the first stack and the metal pattern.

4. The semiconductor device of claim 3, wherein the insulating liner and the interlayer insulating layer are a single layer that is integrally connected.

5. The semiconductor device of claim 3, further comprising a conductive pattern located between the first stack and the interlayer insulating layer.

6. The semiconductor device of claim 5, wherein the conductive pattern includes polysilicon.

7. The semiconductor device of claim 1, wherein the penetration structure comprises:
a metal liner;
an insulating liner surrounding the metal liner; and
the air gap located inside the metal liner.

8. The semiconductor device of claim 7, wherein the metal liner protrudes from an upper surface of the first stack.

9. The semiconductor device of claim 1, wherein the second stack includes third material layers and fourth material layers, the third material layers alternately stacked with the fourth material layers in the vertical direction, and includes the key pattern on a surface of the second stack.

10. The semiconductor device of claim 9, wherein the third material layers and the fourth material layers are stacked in a shape in which they are recessed toward the penetration structure, and the key pattern includes a groove located in a recessed region.

11. The semiconductor device of claim 1, wherein the penetration structure has a smaller width at an upper portion of the penetration structure than at a lower portion of the penetration structure.

12. The semiconductor device of claim 1, wherein the penetration structure is located in a scribe lane region.

13. The semiconductor device of claim 1, further comprising:
a memory cell array including a gate structure located at a level corresponding to the first stack and the second stack;
a peripheral circuit;
a bonding structure electrically connecting the memory cell array to the peripheral circuit.

14. The semiconductor device of claim 1, further comprising:
a gate structure located at a level corresponding to the first stack and the second stack;
a source layer overlapping with the gate structure in the vertical direction; and
a metal wiring line located above the source layer.

15. The semiconductor device of claim 14, further comprising a metal pattern located over the first stack and located at a level corresponding to the metal wiring line.

16. A semiconductor device comprising:
a stack located in a scribe lane region and including first material layers and second material layers, the first material layers are alternately stacked with the second material layers in a vertical direction;
a metal liner extending in the vertical direction through the stack;
an insulating liner surrounding the metal liner;
an air gap located inside the metal liner; and
an interlayer insulating layer overlapping the stack in the vertical direction.

17. The semiconductor device of claim 16, further comprising a conductive pattern located between the stack and the interlayer insulating layer.

18. The semiconductor device of claim 16, further comprising a metal pattern overlapping with the interlayer insulating layer in the vertical direction and in contact with the air gap or the metal liner.

19. The semiconductor device of claim 16, wherein the insulating liner and the interlayer insulating layer are a single layer that is integrally connected.
